(19) United States
(12) Patent Application Publication
(10) Pub. No.: US 2009/0084421 A1
(43) Pub. Date: Apr. 2, 2009

(54) THERMOELECTRIC DEVICES

(75) Inventors: Larry C. Olsen, Richland, WA (US); John G. DeSteese, Kennewick, WA (US)

Correspondence Address: KLARQUIST SPARKMAN, LLP, 121 SW SALMON STREET, SUITE 1600, ONE WORLD TRADE CENTER, PORTLAND, OR, 97204, US

(73) Assignee: Battelle Memorial Institute

(21) Appl. No.: 11/864,877

(22) Filed: Sep. 28, 2007

(51) Int. Cl. H01L 35/02; H01L 35/34; C23C 14/34

(52) U.S. Cl. 136/201; 136/200; 204/192.12; 204/192.25

(57) ABSTRACT

One or more thin-film layers of thermoelectric material are formed on one or both sides of a substrate (e.g., a flexible substrate). In some embodiments, the thin-film layers have features that scatter phonons. A flexible substrate and its attached layers of thermoelectric material can be rolled up and/or arranged in a serpentine configuration for incorporation into a thermoelectric power source. In some embodiments, thin-film layers on one side of a substrate form a single, continuous thermoelectric element. In particular embodiments, one or more thin-film layers are fabricated on a substrate using an arrangement where the substrate is wrapped around a wheel and rotated one or more times past a sputtering device or other device for depositing material.

### ACKNOWLEDGMENT OF GOVERNMENT SUPPORT

This invention was made with Government support under Contract DE-AC06-76RL01830. The Government has certain rights in the invention.

### FIELD

The present disclosure relates to thermoelectric devices.

### BACKGROUND

The increasing use of portable electronics has driven research in the area of portable electric generators. Thermoelectric (TE) power sources have been found to be especially useful. TE power sources typically comprise three parts: a heat source, a heat sink, and a thermopile. The thermopile, comprising a number of thermocouples (also referred to as “couples” or “TE modules”) connected in series, serves to convert some of the thermal energy into electrical energy. TE power sources generate electric power based on creating a thermal gradient across the thermocouples of the thermopile. The TE power source operates to convert the thermal energy to electric power by accepting thermal energy on a “hot” side or junction, passing it through the thermopile and rejecting heat to a “cold” side or junction.

Traditionally, relatively small TE power sources have limited efficiency and electric potential. Difficult syntheses have limited the construction of many TE devices to bulk materials or minute quantities—each suffering from shortcomings in size or performance.

For example, currently available TE modules have structures where each distinct thermoelement typically has a length and width on the order of a few millimeters. Generally, these modules cannot provide voltages that readily match the input requirements of many devices, including power conditioning electronics.

A practical approach to building relatively high-voltage, thin-film TE devices in relatively small packages is needed.

### SUMMARY

One or more thin-film layers of thermoelectric material are formed on one or both sides of a substrate (e.g., a flexible substrate). In some embodiments, the thin-film layers have nanostructures that scatter phonons. A flexible substrate and its attached layers of thermoelectric material can be rolled up and/or arranged in a serpentine configuration for incorporation into a thermoelectric power source as a thermoelement. In some embodiments, thin-film layers on one side of a substrate form a single, continuous thermoelectric element. In particular embodiments, one or more thin-film layers are fabricated on a substrate using an arrangement where the substrate is wrapped around a wheel and rotated one or more times past a sputtering device or other device for depositing material.

In some embodiments, an apparatus comprises a first rolled up section of one or more layered thermoelectric materials on a first flexible substrate, wherein the first flexible substrate has a width, and wherein the one or more layered thermoelectric materials form a first continuous thermoelement with a first length substantially longer than the width of the first flexible substrate. In some cases, the first continuous thermoelement is on a first side of the first flexible substrate, and the one or more layered thermoelectric materials form on a second side of the first flexible substrate a second continuous thermoelement with a second length substantially longer than the width of the first substrate. In additional embodiments a second rolled up section of one or more layered thermoelectric materials on a second flexible substrate, wherein the first rolled up section of one or more layered thermoelectric materials is electrically coupled to the second rolled up section of one or more layered thermoelectric materials. In further embodiments the first rolled up section of one or more layered thermoelectric materials comprises an end with a metallic film. In some embodiments the apparatus further comprises a thermally conductive surface thermally coupled to the first rolled up section of one or more layered thermoelectric materials on the first flexible substrate and electrical leads electrically coupled to the first rolled up section of one or more layered thermoelectric materials.

In further embodiments, a method comprises: storing a portion of a flexible substrate in a wrapped configuration; moving the portion of the flexible substrate a first time near an opening configured thermoelectric material in order to provide a first thermoelectric material deposit; moving the portion of the flexible substrate a second time near the opening in order to provide a second thermoelectric material deposit. In particular embodiments, storing the portion of the flexible substrate in the wrapped configuration comprises wrapping the portion of the flexible substrate around a surface. The surface can comprise a wheel or a rectangular surface. In some embodiments the flexible substrate comprises a first side and a second side, the method further comprising turning the flexible substrate from the first side to the second side after moving the portion of the flexible substrate near an opening the first time to provide the first thermoelectric material deposit and before moving the portion of the flexible substrate near the opening the second time to provide the second thermoelectric material deposit. In some cases moving the portion of the flexible substrate across the first opening to provide the first thermoelectric material deposit comprises sputtering the first thermoelectric material deposit onto the portion of the flexible substrate. In additional embodiments the first thermoelectric material deposit and the second thermoelectric material deposit are configured to form a one or more phonon barriers on the flexible substrate. In some cases the method further comprises rolling the flexible substrate and the first and second thermoelectric material deposits into a cylinder configuration.

Some embodiments of an apparatus comprise: a flexible substrate having a width, a length, a first surface and a second surface; and a first plurality of stacked thin-film layers comprising one or more semiconductor thermoelectric materials on the flexible substrate, wherein one or more portions of the plurality of stacked thin-film layers form nanostructures and are configured to scatter phonons. In additional embodiments the apparatus further comprises a second plurality of stacked thin-film layers comprising one or more semiconductor thermoelectric materials on the flexible substrate, wherein the first plurality of stacked thin-film layers is substantially on the first surface of the flexible substrate, and wherein the second plurality of stacked thin-film layers is substantially on the second surface of the flexible substrate.

In a further embodiment, a method comprises forming a plurality of stacked thin-film layers of one or more semiconductor thermoelectric materials on a flexible substrate, wherein the flexible substrate has a width, and wherein the one or more layered semiconductor thermoelectric materials form a continuous thermoelement with a length substantially longer than the width of the flexible substrate. In some cases the plurality of stacked thin-film layers forms one or more nanostructures for scattering phonons in the plurality of stacked thin-film layers. In additional embodiments forming the plurality of stacked thin-film layers of one or more semiconductor thermoelectric materials on the flexible substrate comprises sputtering the one or more semiconductor thermoelectric materials onto the flexible substrate. In particular embodiments the method further comprises forming the plurality of thin-film layers of one or more semiconductor thermoelectric materials and the flexible substrate into a serpentine configuration. In further embodiments the method further comprises rolling up the plurality of thin-film layers of one or more semiconductor thermoelectric materials and the flexible substrate. In some embodiments the method further comprises incorporating the plurality of stacked thin-film layers of one or more semiconductor thermoelectric materials and the flexible substrate into a thermoelectric generator.

Generally, any of the technologies disclosed herein can be used in TE power sources. In some embodiments, a thermoelectric power source comprises: a p-type thermoelectric element comprising a first rolled up section of one or more layered sputter-deposited thermoelectric materials on a first flexible substrate, wherein the one or more layered thermoelectric materials form a continuous p-type thermoelement with a first length substantially longer than the width of the first flexible substrate; an n-type thermoelectric element comprising a second rolled up section of one or more layered sputter-deposited thermoelectric materials on a second flexible substrate, wherein the one or more layered thermoelectric materials form a continuous p-type thermoelement with a second length substantially longer than the width of the second flexible substrate; a first thermally conductive plate thermally coupled to the p-type thermoelectric element and the n-type thermoelectric element; a second thermally conductive plate thermally coupled to the p-type thermoelectric element and the n-type thermoelectric element; a first electrical lead electrically coupled to the p-type thermoelectric element; and a second electrical lead electrically coupled to the n-type thermoelectric element.

### BRIEF DESCRIPTION OF THE DRAWINGS

FIG. 1 illustrates one embodiment of a prior art TE power source.

FIG. 2 shows a perspective view of a further embodiment of a TE power source.

FIG. 3 shows a plan view of a flexible substrate on which one or more thin films have been formed.

FIG. 4 shows a cross-sectional view of the flexible substrate and one or more thin films of FIG. 3.

FIG. 5 is a perspective view of one embodiment of a thermoelectric element rolled into a cylinder configuration.

FIGS. 6A and 6B show views of an embodiment of a thermoelectric element with electrically conductive contacts.

FIG. 7 shows a side view of an embodiment of a TE power source incorporating TE elements made using technologies described herein.

FIG. 8 shows a cross-sectional view of the TE power source of FIG. 7.

FIG. 9 shows an embodiment of a system for making one or more thin films of a flexible substrate.

FIG. 10 shows a side view of the system of FIG. 9.

FIG. 11 shows a cross-sectional view of a thin-film substrate formed using the system of FIG. 9.

FIG. 12 shows an embodiment of a system for making one or more thin films on a flexible substrate.

FIG. 13 shows an embodiment of a system for making one or more thin films on a flexible substrate.

FIG. 14 is a chart showing electrical properties of certain p-type thin films grown using a system similar to the one shown in FIG. 9.

FIG. 15 is a chart showing electrical properties of certain p-type thin films grown using a system similar to the one shown in FIG. 9.

FIG. 16 is a chart showing electrical properties of certain n-type films grown on a KAPTON substrate.

FIG. 17 is a chart showing electrical properties of certain n-type films grown on a KAPTON substrate.

FIG. 18 is a perspective view of an embodiment of the system of FIG. 12.

FIG. 19 shows an embodiment of a system for making one or more thin films on a flexible substrate.

### DETAILED DESCRIPTION

Disclosed below are representative embodiments of thermoelectric elements, as well as methods for making and/or using such elements. These representative embodiments should not be construed as limiting in any way. Instead, the present disclosure is directed toward all novel and nonobvious features and aspects of the various disclosed methods, apparatus, and equivalents thereof, alone and in various combinations and subcombinations with one another. The disclosed technologies are not limited to any specific aspect or feature, or combination thereof, nor do the disclosed methods and apparatus require that any one or more specific advantages be present or problems be solved.

As used in this application and in the claims, the singular forms “a”, “an” and “the” include the plural forms unless the context clearly dictates otherwise. Additionally, the term “includes” means “comprises.” The phrase “and/or” can mean “and,” “or,” or “both.”

Although the operations of some of the disclosed methods and apparatus are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods and apparatus can be used in conjunction with other methods and apparatus. Additionally, the description sometimes uses terms like “apply” and “make” to describe the disclosed methods. These terms are high-level abstractions of the actual operations that are performed. The actual operations that correspond to these terms can vary depending on the particular implementation and are readily discernible by one of ordinary skill in the art.

Unless otherwise indicated, all numbers expressing quantities of ingredients, properties such as thicknesses, power levels, and so forth used in the specification and claims are to be understood as being modified by the term “about,” whether explicitly stated or not. Accordingly, unless indicated clearly to the contrary, the numerical parameters set forth are approximations. Further, the term “electrically coupled” does not exclude the presence of intermediate elements between the electrically coupled items.

Technologies described herein can be used in combination with one or more technologies described in: U.S. patent application Ser. No. 10/727,062, titled “Thermoelectric Power Source Utilizing Ambient Energy Harvesting for Remote Sensing and Transmitting” and filed Dec. 2, 2003; U.S. patent application Ser. No. 10/726,744, titled “Thermoelectric Devices and Applications for the Same” and filed Dec. 2, 2003; U.S. patent application Ser. No. 11/004,611, titled “Thermoelectric Devices and Applications for the Same” and filed Dec. 2, 2004; U.S. patent application Ser. No. 10/581,281, titled “Thermoelectric Devices and Applications for the Same” and filed May 31, 2006; and U.S. patent application Ser. No. 11/864,595, titled “Thermoelectric Devices and Applications for the Same” and filed Sep. 28, 2007, all of which are incorporated herein by reference.

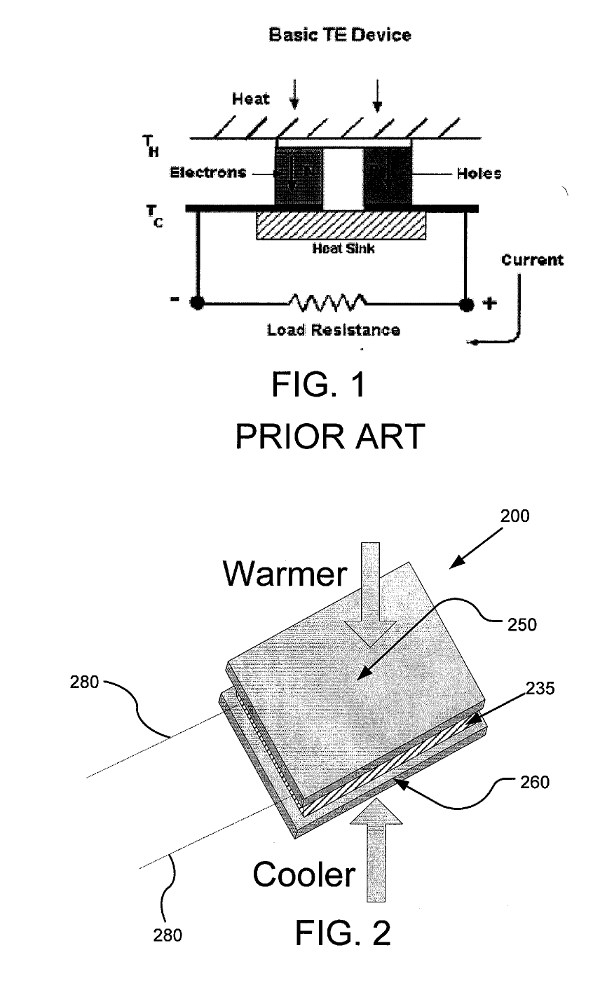

Certain TE power sources and TE thermoelements in particular are formed using semiconductor materials. Semiconductor materials with dissimilar characteristics are connected electrically in series (to form thermocouples) and thermally in parallel, so that two junctions are created. The semiconductor materials are typically n-type and p-type. In a typical thermoelectric device, the electrically conductive connection is formed between the p-type and n-type semiconductor materials. These materials are so named because of their structure: the n-type has more electrons than necessary to complete a perfect molecular lattice structure while the p-type does not have enough electrons to complete a lattice structure. The extra electrons in the n-type material and the holes left in the p-type material are called “carriers.” The carriers are driven from the hot junction to the cold junction as a result of thermal diffusion resulting in an electrical current. For thermoelectric cooling, the electrons and holes transport heat as a result of imposed electrical current. FIG. 1 shows a schematic diagram of a prior art form of such power conversion. Cooling action results from applying a current to the positive and negative terminals of such a device.

A semiconductor TE device's performance is limited by the non-dimensional thermoelectric figure of merit (ZT) of the material, where T is the absolute temperature of the TE device and Z is a thermoelectric figure of merit, Z=sa²/k (where a represents thermoelectric power, s represents electrical conductivity, and k represents thermal conductivity). Typically TE devices are formed of TE materials having relatively high thermoelectric figures of merit. In certain devices, however, the key objective is to produce power at voltages above 1.0 V in as small or compact a device as possible. Some or all of the known TE materials having relatively high thermoelectric figures of merit cannot be deposited as thin films on substrates useful for forming small TE power source devices. For purposes of this application, a “thin film” is generally considered to be a layer of material having a generally uniform thickness between about several Angstroms and tens of microns or hundreds of microns. Thus, although more efficient materials (i.e., materials with high ZT values) are typically better, for many applications it is more important that the resulting device be formed on a flexible substrate and that the film itself be flexible. As a result, although there may be some sacrifice of ZT value, using a TE material depositable on a substrate that allows fabrication of a small device with a relatively high voltage is better for certain applications. In at least some TE power devices using embodiments of technologies disclosed herein, TE conversion efficiency can be improved.

Devices having ZT values of greater than 2.0 have been reported for Bi—Te/Sb—Te superlattices grown on single crystal GaAs. Such devices are not necessarily suitable for many applications where hundreds or thousands of elements must be placed in a relatively small package.

FIG. 2 shows an embodiment of a TE power source 200. The power source 200 comprises a plurality of TE modules 235, which are described below in more detail. Generally, the plurality of TE modules 235 collectively comprises one or more n-type thermoelements and one or more p-type thermoelements formed of semiconductor thin films. As used herein, a “thermocouple” refers to at least one n-type thermoelement electrically coupled to at least one p-type thermoelement. In addition to the array of TE modules 235, the TE power source 200 may comprise thermally conductive plates 250, 260, such as ceramic plates on the upper and lower edges of the substrate 240 (as shown in FIG. 2), a single ceramic plate, a ceramic shoe or other suitable enclosure devices. Electrical leads 280 are connected to the array of TE couples 235 of the TE device 200 to receive and transmit the electrical energy produced by the device.

Some embodiments of the thin film TE power source 200 further comprise a hot junction (or heat source) and a cold junction. The hot junction or heat source can comprise any suitable source depending upon the application of the device, for example a chemical energy source, heat from the environment, a nuclear heat source, or other industrial heat source. The cold junction can comprise any suitable heat removal mechanism constructed or positioned in a manner that allows heat to be relieved from or extracted from the TE power source. For example, the cold junction may comprise a heat pipe arrangement or exposure to the environment by, e.g., convection cooling. As explained below, in particular embodiments a TE power source comprises one or more thermoelements formed on a flexible substrate. The substrate is wound in a coil-like fashion and positioned between hot and cold junctions. In at least some cases, such a configuration provides a relatively small TE power source without sacrificing power output.

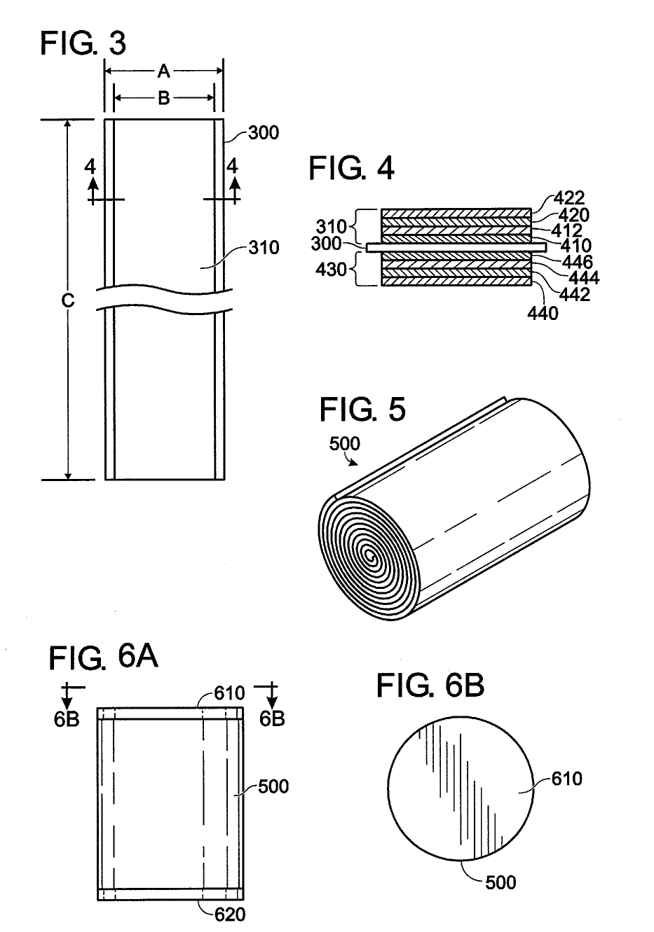

FIG. 3 shows a plan view of a substrate 300 on which one or more thin films 310 have been formed. Generally, the substrate 300 is a flexible substrate, although in some embodiments the substrate comprises a plurality of rigid and/or semi-rigid sections connected such that the substrate as a whole has a degree of flexibility. The substrate 300 has a length C and a width A, generally with C>>A. Although in various embodiments the one or more thin films 310 can be formed in any desired shape, in the embodiment of FIG. 3 the thin films 310 have a length C and a width B, where B<A. In further embodiments, B is approximately equal to A, or B>A. FIG. 4 shows a cross-sectional view of the substrate 300 and the thin films 310, as taken along the line indicated in FIG. 3.

Generally, one or more materials for the substrate 300 are selected based on one or more properties such as: electrical conductivity; thermal conductivity; or compatibility with materials used in the one or more thin films 310 (e.g., reactivity, rate of expansion, adhesion). Additionally, the material can be selected based on its suitability for one or more processes with which the thin films 310 are deposited on the substrate 300. In selected embodiments, the material for the substrate 300 is selected for one or more of: low electrical conductivity (e.g., 0.001-0.1 S/cm); low thermal conductivity (e.g., a thermal conductivity of about 0.001 W/cm/K, which is a factor of 10 below many thermoelectric materials); low reactivity with materials used in the thin films 310 (e.g., reactivity should be negligible over a temperature range of interest); a rate of expansion approximately equal to that of materials used in the thin films 310 (e.g., 10⁻⁶ cm/cm); and adequate adhesion with the materials used in the thin films 310 (e.g., the thin films remain adhered to the substrate after being deposited and rolled up, as described below). With respect to thermal expansion, in some embodiments where thermal expansion coefficients of a substrate and TE materials on the substrate differ by more than a selected amount, at least some consequences of the difference can be mitigated by depositing TE materials on both sides of the substrate. A low electrical conductivity allows the substrate 300 to not significantly affect the Seebeck coefficient and/or the electrical conductivity of the thin films 310. (The Seebeck coefficient is a measure of an induced thermoelectric voltage in a material in response to a temperature difference across that material.) In some embodiments the flexible substrate 300 comprises polyimide (e.g., KAPTON) or a similar material. In further embodiments the flexible substrate 300 comprises an aerogel. In additional embodiments the flexible substrate 300 comprises a first material that has been coated and/or treated with a second material in order to improve selected properties of the first material. Generally, the flexible substrate 300 should be thin, but thick enough to maintain integrity during application of the thin films. Exemplary thicknesses of the flexible substrate 300 include 5 microns, 15 microns and 50 microns. The substrate preferably has negligible impact on the thermal efficiency of the deposited TE film because the thermal conductivity of the substrate is preferably about an order of magnitude lower than that of the TE material it supports. As an example, for an embodiment where a polyimide substrate material and a set of thin film layers (e.g., one or more thin films 310) each have an approximate thickness of 10 to 12 microns, if the thermal conductivity of the polyimide is about 0.001 W/cm/K, the thermal loss of the substrate material can be considered negligible. The substrate is also preferably an electrical insulator so it does not significantly affect the Seebeck coefficient or the electrical conductivity of the thin-film deposit.

In the embodiment of FIG. 4, the thin films 310 comprise four layers 410, 412, 420, 422, and the thin films 430 comprise another four layers 440, 442, 444, 446, but further embodiments encompass other numbers of layers. Generally, a “layer” is a substance bounded by an interface or discrete boundary, although in some embodiments a boundary between two layers is non-discrete due to mixing of material in adjacent layers. In some embodiments one or more films are generally homogenous, while in further embodiments one or more films are at least somewhat heterogeneous. FIG. 4 depicts the substrate 300 as having thin films on two sides, but further embodiments have thin films on only one side of the substrate. In some embodiments the layers 410, 412, 420, 422, 440, 442, 444, 446 each comprise the same thermoelectric material, while in further embodiments at least one of the layers comprises a different thermoelectric material than one of the other layers. Respective thicknesses of the layers 410, 412, 420, 422, 440, 442, 444, 446 can vary among embodiments. Exemplary thicknesses of a layer such as layers 410, 412, 420, 422, 440, 442, 444, 446 include about 10 Å, 100-200 Å and 100-1000 Å. In particular embodiments, one or more of the layers 410, 412, 420, 422, 440, 442, 444, 446 form nanostructures (layered structures on a nanometer scale), and multiple nanostructures formed among layers are sometimes referred to as “multi-layer nanostructures” (MLNS). One or more of the layers 410, 412, 420, 422, 440, 442, 444, 446 act as thermoelements (e.g., n-type or p-type). Exemplary embodiments of particular thermoelectric materials are described below.

Generally, in a TE power source device such as that shown in FIG. 2, it is advantageous to prevent heat flow between the conductive plates 250, 260, as the current generated by the device generally increases with the temperature differential between the plates 250, 260. The concept of a phonon can be used to describe the quantization of heat transfer by lattice vibrations in a solid. Phonons arise as a result of atomic motion in the solid. A phonon can be viewed, for example, as a pulse of atomic motion moving through a lattice. Phonons are responsible for carrying a large part of the thermal energy that passes through the solid, although electrons also carry some heat. Structures that reduce, scatter or block the flow of phonons in a solid can reduce heat transfer in the solid and are sometimes called herein “phonon barriers.” These structures can be made using layered nanostructures with thicknesses on the order of tens or hundreds of nanometers. A particular example of a nanostructure is a superlattice. Layers forming a nanostructure can comprise the same or different materials and are of same, similar or different thicknesses. On a quantum mechanical level, different layers in a nanostructure sometimes have differing electron energy levels. If a layer with relatively low energy levels is positioned between layers with relatively high energy levels, this sometimes results in a “quantum well” in the layer with the relatively low energy levels.

Accordingly, at least some of the layers 410, 412, 420, 422, 440, 442, 444, 446 are constructed so as to scatter phonons, either through phonon barriers at particular locations within the layers, or through structures that are more generally distributed through one or more layers. Examples of such distributed scattering structures include impurities and inclusions, with sizes on the order of, for example, tens of nanometers. To provide phonon barriers, for example, one or more superlattices and/or one or more quantum wells are fabricated using the layers 410, 412, 420, 422, 440, 442, 444, 446. In some embodiments, a phonon barrier is formed at least in part as a result of an interface between two of the layers 410, 412, 420, 422, 440, 442, 444, 446. However, in some embodiments one or more phonon barriers are created as a result of one or more other structures.

Although FIG. 4 shows the thin films 310 as being on only one side of the flexible substrate 300, in further embodiments the thin films 310 are on both sides of the substrate 300. The flexible substrate 300 provides a supporting “scaffold” that allows for manipulation and application of the thin films 310, the thin films 310 having thickness of, for example, 1 to 100 microns and areas of, for example, 1 m², 10 m², or more. Although some embodiments feature thin-film structures that are relatively large, the flexible substrate 300 allows for relatively easy handling of the thin-film structures. In selected embodiments, the thin films 310 form a p-type or n-type “monoelement” that, for example, runs approximately the length of its supporting substrate 300. In at least some embodiments, the flexible substrate 300 is incorporated into a TE device (e.g., a TE power source) along with the thin films 310 formed on the substrate 300. This can allow for fabrication of TE elements without separating the thin films from the substrate on which they were formed.

In some embodiments, elements such as the one depicted in FIGS. 3 and 4 can be incorporated into a TE power source. As shown in FIG. 5, in particular embodiments, an element (including a substrate and one or more thin films) is rolled up to form a thermoelement 500. The element can simply be formed into a coil, or it can be wound about an apparatus such as a spindle (not shown). Although FIG. 5 shows the thermoelement 500 in a cylindrical configuration (with circular or ovoid ends), in further embodiments the thermoelement 500 has a configuration with, for example, triangular or quadrilateral ends. In additional embodiments, the thermoelement 500 is arranged in a serpentine configuration wherein the element is repeatedly folded back on itself. Configurations such as these can provide a section of thermoelectric material that, in at least some cases, can substitute for a conventional cast or sintered thermoelectric element of similar or equal size.

As shown in FIGS. 6A and 6B, in further embodiments the thermoelement 500 comprises electrically conductive contacts 610, 620 on one or both ends of the thermoelement 500. FIG. 6A is a side view of the thermoelement 500 with the contacts 610, 620, and FIG. 6B is a top view of the thermoelement 500 with the contact 610. Generally, the conductive contacts 610, 620 are fabricated such that the interface electrical resistance (e.g., electrical resistance between the contacts 610, 620 and the thin films in the thermoelement 500) is relative low or very low. In some embodiments, the contacts 610, 620 are created using vapor deposition, but in further embodiments additional methods are used. Generally, materials used in making the conductive contacts 610, 620 vary according to the properties of the one or more materials in the thin films of the thermoelement 500. For example, for contacts formed on GAST materials (which are described in more detail below), a first layer comprising tin telluride is deposited on the element 500 with a thickness of 1000-2000 Å. A second layer, comprising one or more metals such as Mo, Ni or Ag, is deposited with a thickness of a few microns. In further embodiments, for PbTe-based materials, one or more metals such as Mo, Au, Ag and Ni are deposited to create the conductive contacts 610, 620. As was similarly explained above with respect to the GAST materials, a tin telluride layer can also be deposited on PbTe-based materials.

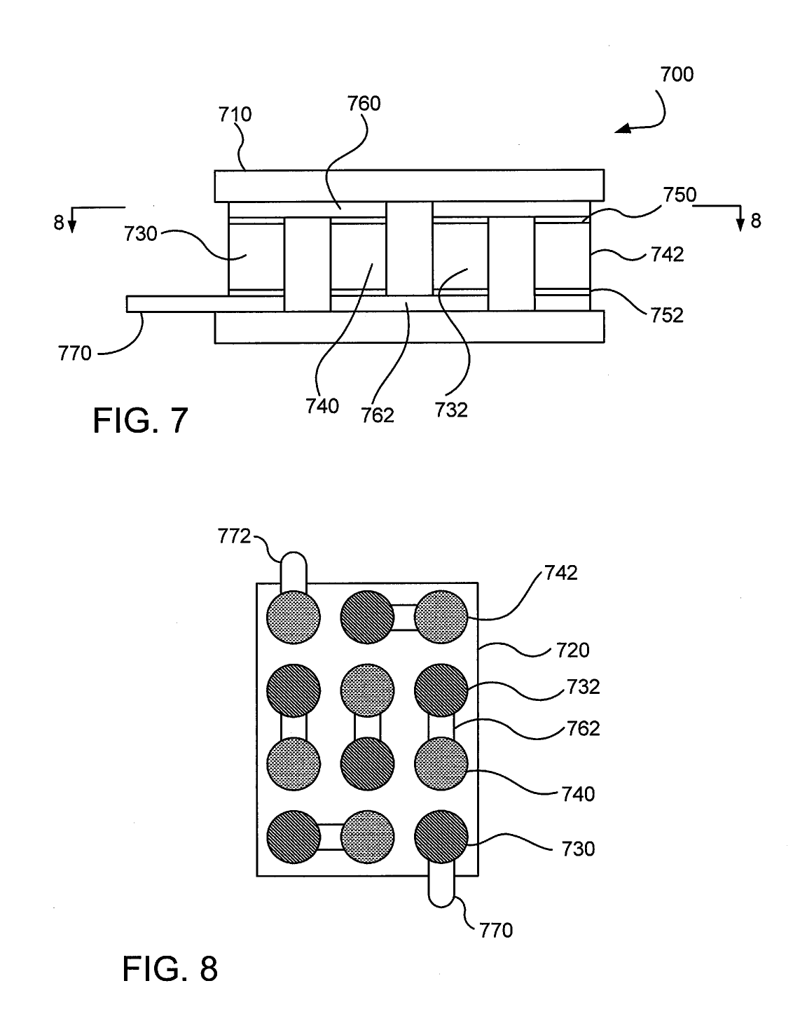

FIG. 7 shows a side view of an exemplary TE power source 700 incorporating thermoelements such as the thermoelement 500. The power source 700 comprises one or more thermally conductive plates 710, 720, one or more n-type thermoelements 730, 732, and one or more p-type thermoelements 740, 742. In the depicted embodiment, the thermoelements 730, 732, 740, 742 feature conductive contacts such as the contacts 750, 752 on the thermoelement 742. The thermoelements 730, 732, 740, 742 are electrically coupled to each other through conductive contacts and through electrically conductive leads such as the lead 760 (which electrically couples the thermoelements 730 and 740) and the lead 762 (which electrically couples the thermoelements 732 and 740). In further embodiments, at least some of the thermoelements are electrically coupled to their respective leads without conductive contacts.

FIG. 8 shows a cross-sectional view of the TE power source 700 taken along the line indicated in FIG. 7. As seen in this view, the depicted embodiment comprises an array of 12 thermoelements, with the cross-sections of the six n-type thermoelements shown with a diagonal-line fill and the cross-sections of the six p-type thermoelements shown with a dotted fill. FIG. 8 also shows electrical leads 770, 772, which can allow the power source 700 to be electrically coupled to other devices (e.g., to allow for a current to be drawn from or provided to the power source 700). To improve clarity, the electrical lead 772 is omitted from the view of FIG. 7.

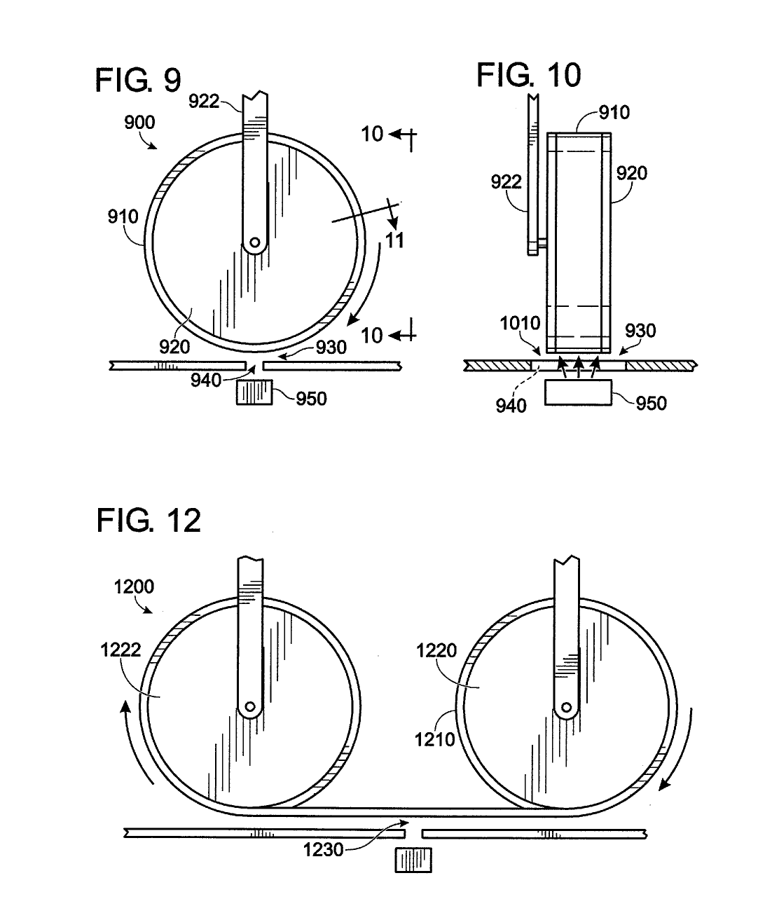

FIG. 9 shows an exemplary embodiment of a system 900 for making one or more thin films on a flexible substrate, similar to the flexible substrate 300. A flexible substrate 910 is wrapped around at least a portion of a wheel 920 (e.g., the flexible substrate 910 can form a loop around the wheel 920). The dimensions of the substrate 910 vary among different embodiments, but in one embodiment it is 50 mm wide, 25 microns thick and 1 m long. The wheel is supported by a structure such as an arm 922. As the wheel 920 rotates (e.g., at a speed of 3 RPM), at least a portion of the flexible substrate 910 passes over a region 930 from which one or more thermoelectric materials are emitted and deposited on the flexible substrate 910. For some substrate materials, the substrate 910 is heated before material is deposited on the substrate. This can be done using, for example, lamps or other heating devices. In further embodiments the substrate 910 is heating by heating the wheel 920 itself. In the depicted example, the flexible substrate 910 passes over an aperture 940 and a sputtering device 950. In some embodiments the aperture 940 reduces application of material by the sputtering device 950 at certain angles (e.g., at oblique angles), which may be undesirable. One or more rotations of the wheel 920 can be used to deposit multiple layers of one or more materials on the on the flexible substrate 910. In particular embodiments, each revolution of the wheel 920 is used to deposit another structure (e.g., a different material) on the flexible substrate 910. For further embodiments, a given area of the substrate 910 (e.g., a material that has been deposited on the given area) is treated by exposure to, for example, one or more of laser light, heat and a gas, potentially affecting the structure of the resulting layer. Accordingly, in at least some embodiments MLNS can be fabricated on the substrate 910 with varying degrees of particularity. After a selected number of layers have been deposited and/or a selected layer thickness has been achieved on the substrate 910, the substrate 910 can be removed from the wheel 920 and rolled up to form a thermoelement as described above. In some embodiments the films have a total thickness of 100 microns.

FIG. 10 shows a side view of the system 900. This particular view also depicts a thermoelectric material (represented by arrows 1010) being deposited by the sputtering device 950 onto the flexible substrate 910. In further embodiments, additional deposition methods can be used in place of and/or in addition to sputtering (e.g., resistance heating, laser ablation, vapor deposition, spraying and post-heat treatment, e-beam evaporation and/or other methods).

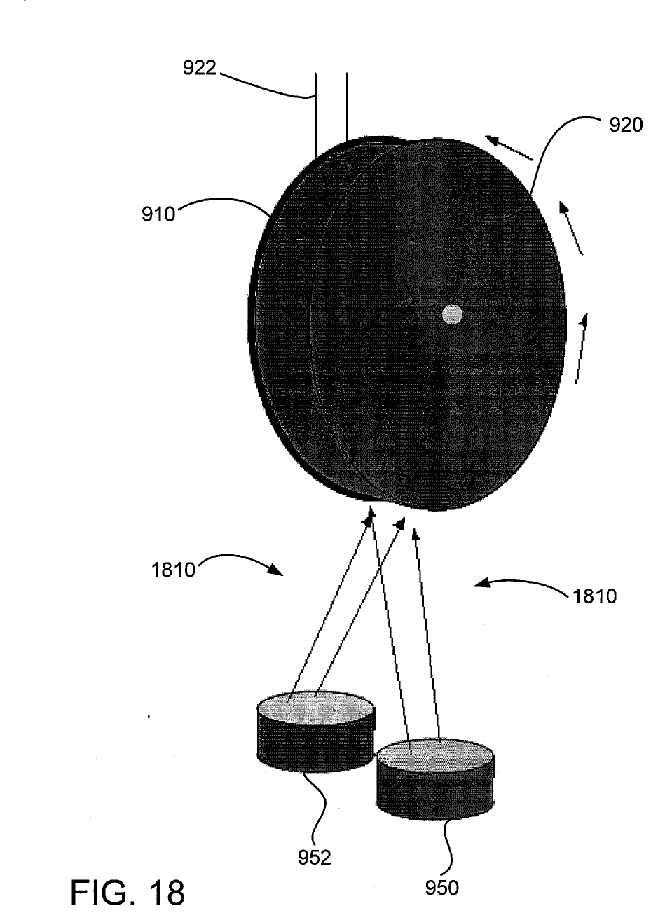

FIG. 18 shows a perspective view of the system 900 with an additional sputtering device 950. In this view, the sputtering devices 950 are depositing thermoelectric material 1810 on the substrate 910 as the wheel 920 rotates. In particular embodiments, each sputtering device 950 deposits a different material on the substrate 910.

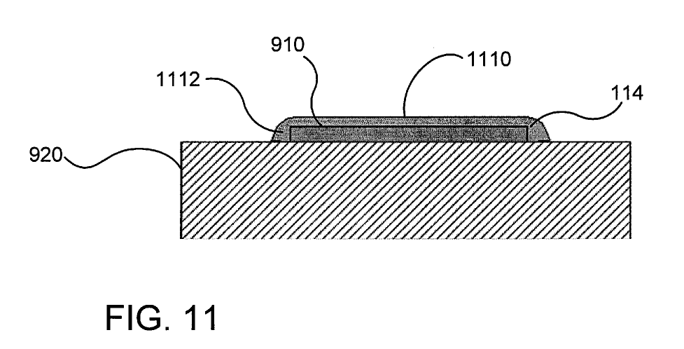

FIG. 11 shows a side cross-sectional view of the flexible substrate 910 mounted on the wheel 920, as indicated in FIG. 9. Although not shown in FIGS. 9 and 10, FIG. 11 depicts a cross-section of a thin layer 1110 of thermoelectric material that has been deposited on the flexible substrate 910. In the depicted embodiment, the thin layer 1110 has been formed such that its width exceeds that of the substrate 910, as shown at overlaps 1112, 1114. In at least some embodiments, a thin film that is configured to overlap a supporting substrate allows for better electrical contact between the rolled up thin film and conductive contacts such as the contacts 750, 752 described above.

FIG. 12 shows a further embodiment of a system 1200 for making a thermoelement on a flexible substrate 1210. A first portion of the flexible substrate 1210 is wrapped around at least a portion of a first wheel 1220, while a second portion of the flexible substrate 1210 is wrapped around a second wheel 1222, similar to, for example, the configuration of a tape in a tape recorder. The wheels 1220, 1222 rotate to pass a portion of the flexible substrate 1210 over a region 1230 from which one or more thermoelectric materials are emitted and deposited on the flexible substrate 1210. In some embodiments, the portion of the substrate 1210 over the region 1230 is heated. Together, the wheels 1220, 1222 can store a flexible substrate 1210 that, for example, is longer than the circumference of either wheel 1220 or 1222.

FIG. 19 shows a further embodiment of a system 1900 for making a thermoelement on a flexible substrate 1910. The flexible substrate 1910 is wrapped around two wheels 1920, 1922 in a loop. The wheels 1920, 1922 rotate to pass a portion of the flexible substrate 1910 over a region 1930 from which one or more thermoelectric materials are emitted and deposited on the flexible substrate 1910. In some embodiments, the portion of the substrate 1910 over the region 1930 is heated. Together, the wheels 1920, 1922 can store a flexible substrate 1910 that, for example, is longer than the circumference of either wheel 1920 or 1922.

In additional embodiments, further configurations can be used to accommodate relatively long flexible substrates, for example, a configuration where a portion of the flexible substrate is placed in a storage area (e.g., bunched up or folded up) before and/or after one or more thermoelectric materials are deposited on one or more regions of the substrate. In at least some embodiments, the flexible substrate is turned over as a result of rotating one or more wheels, allowing for thermoelectric material to be applied to two sides of the substrate. For example, in an embodiment similar to the system 1900, the substrate 1910 can be configured similar to a Mobius strip.

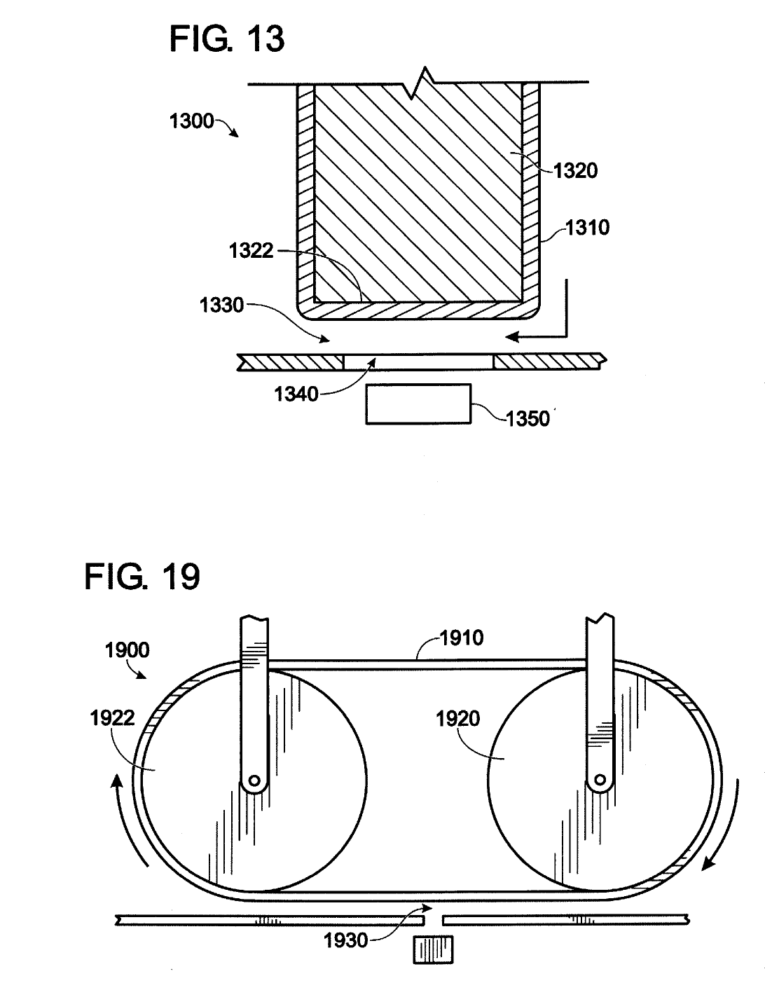

FIG. 13 shows another exemplary embodiment of a system 1300 for making a thermoelement on a flexible substrate 1310. In such embodiments, the flexible substrate 1310 slides along the surface of a block 1320 and past a region 1330 from which one or more thermoelectric materials are emitted and deposited on the flexible substrate 1310. In the depicted embodiment, the block 1320 comprises a rectangular surface 1322, but in further embodiments surfaces having other shapes can be used.

Generally, thin films described herein can be made using any thermoelectric material that can be deposited as a film, including one or more of semiconductor, amorphous and metallic materials. With respect to metallic materials, in some embodiments an n-type element comprises alumel films, and/or p-type elements comprise chromel films. The absolute value of the Seebeck coefficient of such metallic materials is on the order of 30 μV/° C., and the electrical conductivity is much greater than 1000 ohm⁻¹cm⁻¹. Exemplary amorphous materials include amorphous silicon and amorphous SiGe alloys.

In some embodiments, including some embodiments using configurations such as those shown in FIGS. 9, 10, 12 and 13, one or more thermoelectric compounds are deposited on a flexible substrate by co-sputtering from two or more targets. In particular embodiments, certain of the thermoelectric compounds are formed using various proportions of BiTe materials. In further embodiments, certain of the thermoelements are formed of sputter deposited thin films containing various proportions of Ge, Ag, Sb and Te as p-type material and Ag, Pb and Te as n-type material. The above materials may be referred to herein as “GAST” or “GAST materials.” GAST materials can be distinguished from known thermoelectric materials of the form (AgSbTe₂)₁₋ₓ(GeTe)ₓ p-type thin films and AgₓPbTe n-type thin films, as GAST materials have no single or specific value of the compositional fractions (1−x) and x. In contrast, the disclosed p-type GAST materials may be achieved within the following ranges of composition:

Ge—Trace amount to about 25 Atomic %

Ag—Trace amount to about 10 Atomic %

Sb—Trace amount to about 20 Atomic %

Te—about 60 to 90 Atomic %

In at least some embodiments, process variables that can be changed to adjust one or more properties of the deposited material (e.g., the thickness of the deposited material) include the temperature of the flexible substrate, and power applied to the one or more targets. Table 1 shows exemplary process parameters for co-sputtering in embodiments using AgSbTe₂ and GeTe targets. Table 2 shows an exemplary composition of GAST thermoelectric material. Further embodiments use Sb₂Te₃ in place of (AgSbTe₂)₁₋ₓ. The target for each material had a 2.0-in diameter.

TABLE 1
Typical process parameters for co-sputtering in
embodiments using AgSbTe₂ and GeTe targets.

| Substrate | Sputtering Gas | Power to AgSbTe₂ | Power to GeTe |
|---|---|---|---|
| Temperature | Pressure | Target | Target |
| 300-350° C. (e.g., | 3 mTorr | 1.3 W/cm² | 3.6 W/cm² |
| 330° C.) | | | |

TABLE 2
Exemplary composition of GAST thermoelectric material.

| Element | Atomic % |
|---|---|
| Ge | 13.6 |
| Ag | 1.5 |
| Sb | 5.7 |
| Te | 79.2 |

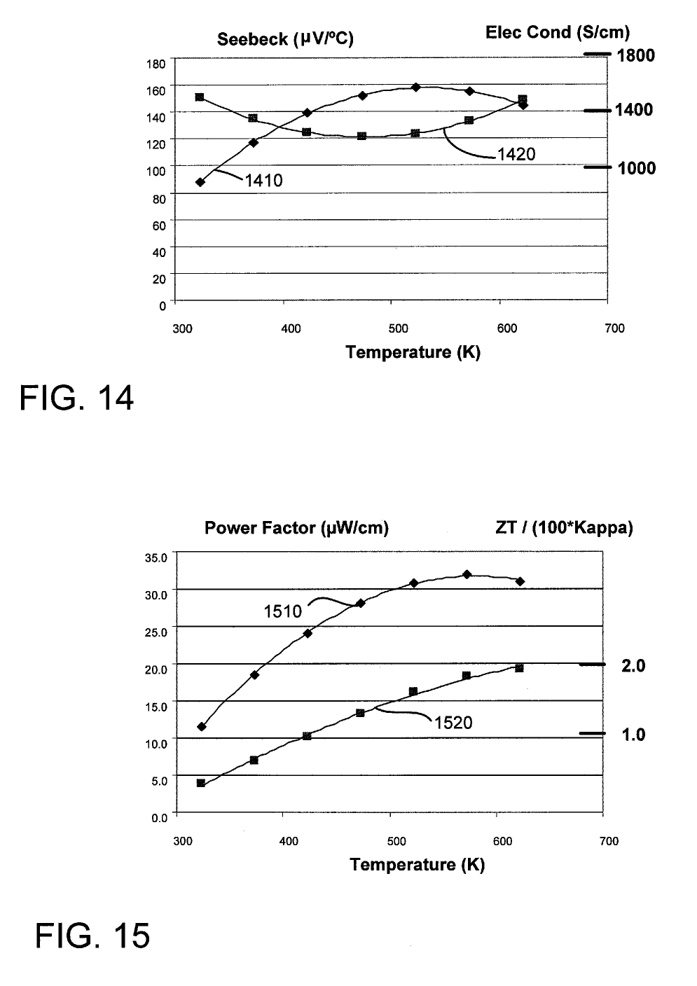

FIG. 14 is a chart showing measured electrical properties of thin films grown using a system similar to that depicted in FIG. 9, using a wheel with a diameter of 32 cm in a stainless steel sputtering chamber in the shape of a cube, with dimensions of 1 m on each side. To obtain the results show in FIG. 14, the chamber was evacuated to a pressure of 10⁻⁶ to 10⁻⁷ Torr and back filled with a high-purity argon gas to a pressure of 1 to 3 mTorr. The wheel was rotated at a rate of 3 RPM. The points on line 1410 indicate Seebeck coefficient values for the thin films, and the points on line 1420 indicate electrical conductivity values for the thin films. FIG. 15 is a chart showing calculated electrical properties for the same thin films. The points on line 1510 indicate the power factor, while the points on the line 1520 indicate the ZT/(100*κ), where κ is the thermal conductivity of the deposited films. The power factor P was calculated as:

P=(Electrical_Conductivity)×(Seebeck_Coefficient)²×10⁶ (1)

The figure of merit ZT was calculated as:

$$ZT = \frac{P \times T \times {10}^{- 6}}{κ} \qquad ( 2 )$$

where T is the temperature at which measurements were taken (in Kelvins) and κ is in W/cm/K. Calculations using Eq. 2 were made assuming κ=0.01 W/cm/K.

Although FIGS. 14 and 15 show measured or calculated values in the temperature range of 300-650 K, at least some of the technologies described herein can be used to fabricate thin films on flexible substrates that are suitable for use in other temperature ranges.

In further embodiments in which one or more n-type elements are made, a first sputtering target contains PbTe and a second sputtering target contains Ag, Te or PbSe. A set of experimental results, shown in Table 3, was obtained by using these materials to grow n-type PbTe-based films on a KAPTON substrate. Although these results were obtained by positioning the substrates 5 inches from sputtering targets in a standard sputtering chamber, rather than using a configuration similar to those described in FIGS. 9, 10, 12 and 13, the results are similar to results that can be obtained using at least some embodiments of technologies described herein.

TABLE 3
Exemplary parameters growth of n-type PbTe-based films On KAPTON.

| Substrate | Sputtering | | | | Electrical | Seebeck |
|---|---|---|---|---|---|---|
| Temperature | Gas Press | Power | Power Other | Growth | Conductivity | Coefficient |
| (° C.) | (mTorr) | PbTe (W) | Target (W) | Rate (Å/s) | (ohm⁻¹cm⁻¹) | (μV/° C.) |
| Ambient | 3.0 | 60 | Ag: 1 | 4.4 | 460 | −87.3 |
| Ambient | 3.0 | 60 | Ag: 5 | 4.4 | 30° C.: 503 | 30° C.: −87.1 |
| | | | | | 250° C.: 795 | 250° C.: −204 |
| 300° C. | 3.0 | 30 | PbSe: 30 | 4.2 | 30° C.: 101 | 30° C.: −171 |
| Ambient | 3.0 | 60 | Te: 10 | 5.2 | 30° C.: 66 | 30° C.: −179 |
| Ambient | 1.0 | 60 | Te: 10 | 5.0 | 30° C.: 307 | 30° C.: −109 |

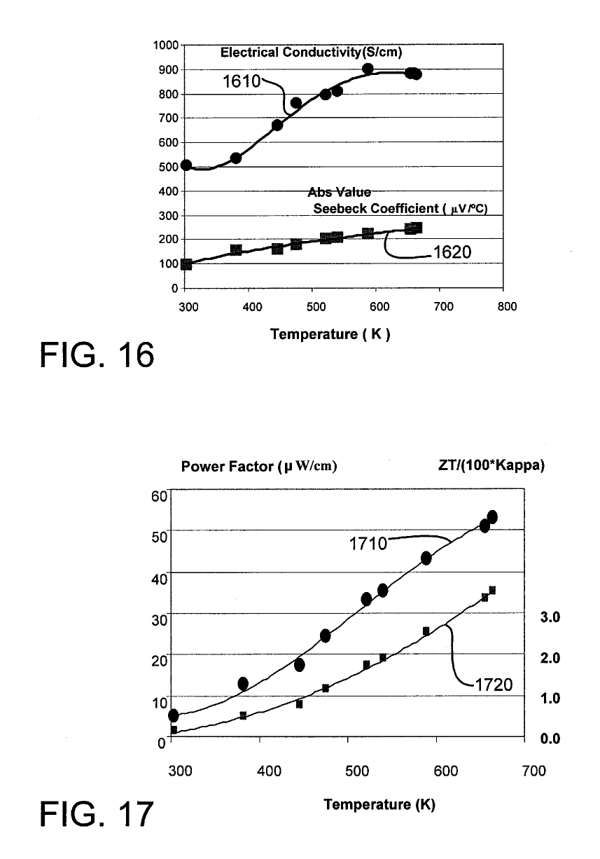

To obtain the results shown in Table 3, the sputter deposition chamber was evacuated to a pressure of 10⁻⁶ Torr and the chamber was then filled with purified argon to the system sputtering gas pressure (e.g., 3.0 mTorr). Substrates were ion cleaned for 3 to 5 minutes using an ion gun in the presence of a gas consisting of argon with approximately 1 atomic percent of oxygen. After cleaning target surfaces for 3 to 5 minutes by establishing plasmas above the targets, film deposition was carried out. After deposition, the thermoelectric thin films were characterized. The thickness was measured with a profilometer. The electrical conductivity and Seebeck coefficient also were determined for the deposited n-type thin films, as shown in FIG. 16 by points on lines 1610, 1620, respectively. FIG. 17 shows the calculated power factor and ZT/(100*κ) for the deposited n-type films by the points on lines 1710, 1720, respectively.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

We claim:

1. An apparatus comprising a first rolled up section of one or more layered thermoelectric materials on a first flexible substrate, wherein the first flexible substrate has a width, and wherein the one or more layered thermoelectric materials form a first continuous thermoelement with a first length substantially longer than the width of the first flexible substrate.

2. The apparatus of claim 1, wherein the first continuous thermoelement is on a first side of the first flexible substrate, and wherein the one or more layered thermoelectric materials form a second continuous thermoelement with a second length substantially longer than the width of the first substrate on a second side of the first flexible substrate.

3. The apparatus of claim 1, further comprising a second rolled up section of one or more layered thermoelectric materials on a second flexible substrate, wherein the first rolled up section of one or more layered thermoelectric materials is electrically coupled to the second rolled up section of one or more layered thermoelectric materials.

4. The apparatus of claim 1, wherein the first rolled up section of one or more layered thermoelectric materials comprises an end with a metallic film.

5. The apparatus of claim 1, further comprising:
a thermally conductive surface thermally coupled to the first rolled up section of one or more layered thermoelectric materials on the first flexible substrate;
and electrical leads electrically coupled to the first rolled up section of one or more layered thermoelectric materials.

6. A method comprising:
storing a portion of a flexible substrate in a wrapped configuration;
moving the portion of the flexible substrate a first time near an opening configured thermoelectric material in order to provide a first thermoelectric material deposit; and
moving the portion of the flexible substrate a second time near the opening in order to provide a second thermoelectric material deposit.

7. The method of claim 6, wherein storing the portion of the flexible substrate in the wrapped configuration comprises wrapping the portion of the flexible substrate around a surface.

8. The method of claim 7, wherein the surface is on a wheel.

9. The method of claim 7, wherein the surface is a rectangular surface.

10. The method of claim 6, wherein the flexible substrate comprises a first side and a second side, the method further comprising turning the flexible substrate from the first side to the second side after moving the portion of the flexible substrate near the opening the first time to provide the first thermoelectric material deposit and before moving the portion of the flexible substrate near the opening the second time to provide the second thermoelectric material deposit.

11. The method of claim 6, wherein moving the portion of the flexible substrate across the first opening to provide the first thermoelectric material deposit comprises sputtering the first thermoelectric material deposit onto the portion of the flexible substrate.

12. The method of claim 6, wherein the first thermoelectric material deposit and the second thermoelectric material deposit are configured to form one or more phonon barriers on the flexible substrate.

13. The method of claim 6, further comprising rolling the flexible substrate and the first and second thermoelectric material deposits into a cylinder configuration.

14. An apparatus comprising:
a flexible substrate having a width, a length, a first surface and a second surface; and
a first plurality of stacked thin-film layers comprising one or more semiconductor thermoelectric materials on the flexible substrate, wherein one or more portions of the plurality of stacked thin-film layers form nanostructures and are configured to scatter phonons.

15. The apparatus of claim 14, further comprising a second plurality of stacked thin-film layers comprising one or more semiconductor thermoelectric materials on the flexible substrate, wherein the first plurality of stacked thin-film layers is substantially on the first surface of the flexible substrate, and wherein the second plurality of stacked thin-film layers is substantially on the second surface of the flexible substrate.

16. A method comprising forming a plurality of stacked thin-film layers of one or more semiconductor thermoelectric materials on a flexible substrate, wherein the flexible substrate has a width, and wherein the one or more layered thermoelectric materials form a continuous thermoelement with a length substantially longer than the width of the flexible substrate.

17. The method of claim 16, wherein the plurality of stacked thin-film layers forms one or more nanostructures for scattering phonons in the plurality of stacked thin-film layers.

18. The method of claim 16, wherein forming the plurality of stacked thin-film layers of one or more semiconductor thermoelectric materials on the flexible substrate comprises sputtering the one or more semiconductor thermoelectric materials onto the flexible substrate.

19. The method of claim 16, further comprising forming the plurality of thin-film layers of one or more semiconductor thermoelectric materials and the flexible substrate into a serpentine configuration.

20. The method of claim 16, further comprising rolling up the plurality of thin-film layers of one or more semiconductor thermoelectric materials and the flexible substrate.

21. The method of claim 16, further comprising incorporating the plurality of stacked thin-film layers of one or more semiconductor thermoelectric materials and the flexible substrate into a thermoelectric generator.

22. A thermoelectric power source comprising:
a p-type thermoelectric element comprising a first rolled up section of one or more layered sputter-deposited thermoelectric materials on a first flexible substrate, wherein the one or more layered thermoelectric materials form a continuous p-type thermoelement with a first length substantially longer than the width of the first flexible substrate;
an n-type thermoelectric element comprising a second rolled up section of one or more layered sputter-deposited thermoelectric materials on a second flexible substrate, wherein the one or more layered thermoelectric materials form a continuous p-type thermoelement with a second length substantially longer than the width of the second flexible substrate;
a first thermally conductive plate thermally coupled to the p-type thermoelectric element and the n-type thermoelectric element;
a second thermally conductive plate thermally coupled to the p-type thermoelectric element and the n-type thermoelectric element;
a first electrical lead electrically coupled to the p-type thermoelectric element; and
a second electrical lead electrically coupled to the n-type thermoelectric element.
